(19) United States
(12) Patent Application Publication
(10) Pub. No.: US 2026/0075738 A1
(43) Pub. Date: Mar. 12, 2026

(54) ELECTRONIC ASSEMBLY AND CHASSIS ASSEMBLY

(71) Applicants: INVENTEC (PUDONG) TECHNOLOGY CORPORATION, Shanghai (CN); INVENTEC CORPORATION, Taipei City (TW)

(72) Inventors: Po-Feng CHEN, Taipei City (TW); Wei-Ming WU, Taipei City (TW); Chih-Wei CHUANG, Taipei City (TW)

(73) Assignees: INVENTEC (PUDONG) TECHNOLOGY CORPORATION, Shanghai (CN); INVENTEC CORPORATION, Taipei City (TW)

(21) Appl. No.: 19/191,716

(22) Filed: Apr. 28, 2025

(30) Foreign Application Priority Data
Sep. 11, 2024 (CN) 202411273250.2

(51) Int. Cl. H05K 7/14

(52) U.S. Cl. CPC H05K 7/1461; H05K 7/1415; H05K 7/1429; H05K 7/1489

(57) ABSTRACT

An electronic assembly and a chassis assembly, wherein the electronic assembly comprises a chassis, a riser card assembly, and a display card assembly. The riser card assembly comprises an assembly bracket and a riser card. The assembly bracket comprises a bracket body and a handle including two mount parts and a handheld part. The riser card is disposed on the bracket body. The display card assembly comprises a tray, a display card and a restriction cover. The display card is disposed on the tray and electrically connected to the riser card. The restriction cover is disposed on a side of the tray. The bracket body and the tray are slidably disposed on the chassis along different directions. When the tray is mounted on the chassis, the restriction cover covers the handheld part, thereby preventing the handle from allowing the bracket body to slide relative to the chassis.

### CROSS-REFERENCE TO RELATED APPLICATIONS

This non-provisional application claims priority under 35 U.S.C. § 119(a) on Patent Application No(s). 202411273250.2 filed in China, on Sep. 11, 2024, the entire contents of which are hereby incorporated by reference.

### BACKGROUND OF THE INVENTION

### Technical Field of the Invention

The invention relates to an electronic assembly and a chassis assembly, more particularly to an electronic assembly including a display card assembly and a riser card assembly, and a chassis assembly configured for a display card and a riser card to be disposed thereon.

### Description of the Related Art

In general, in order to improve space utilization, various electronic components are densely disposed in a server chassis. Thus, the electrical connection between an electronic component with large volume, such as a display card, and a motherboard is usually realized by a riser card.

However, the display card and the riser card are commonly mounted in the server chassis along different directions. Thus, if the riser card is removed from the server chassis before the display card is removed from the server chassis, the connectors on the display card and the riser card that are connected will be damaged.

### SUMMARY OF THE INVENTION

The invention is to provide an electronic assembly including a restriction cover and a chassis assembly to prevent the riser card assembly from being removed from the server chassis before the display card is removed from the server chassis, thereby preventing the connectors of the display card assembly and the riser card assembly that are connected from being damaged.

One embodiment of the invention discloses an electronic assembly including a chassis, a riser card assembly, and a display card assembly. The riser card assembly includes an assembly bracket and a riser card. The assembly bracket includes a bracket body and a handle. The handle includes two mount parts and a handheld part. The handheld part connected to the two mount parts. The two mount parts pivotally connected to opposite sides of the bracket body, respectively. The riser card is disposed on the bracket body. The bracket body is slidably disposed on the chassis along a first mount direction. The display card assembly includes a tray, a display card and a restriction cover. The display card is disposed on the tray and electrically connected to the riser card. The restriction cover is disposed on a side of the tray. The tray is slidably disposed on the chassis along a second mount direction. The first mount direction is different from the second mount direction. When the tray is mounted on the chassis, the restriction cover covers the handheld part and prevents the handheld part from pivotally rotating the two mount parts relative to the bracket body, thereby preventing the handle from allowing the bracket body to slide relative to the chassis.

Another embodiment of this invention provides a chassis assembly configured to dispose a display card and a riser card. The chassis assembly includes a chassis, an assembly bracket, a tray, and a restriction cover. The assembly bracket includes a bracket body and a handle. The handle includes two mount parts and a handheld part. The handheld part is connected to the two mount parts. The two mount parts are pivotally connected to opposite sides of the bracket body, respectively. The bracket body is slidably disposed on the chassis along a first mount direction and configured to dispose the riser card. The tray is slidably disposed on the chassis along a second mount direction and configured to dispose the display card. The first mount direction is different from the second mount direction. The restriction cover is disposed on a side of the tray. When the tray is mounted on the chassis, the restriction cover covers the handheld part and prevents the handheld part from pivotally rotating the two mount parts relative to the bracket body, thereby preventing the handle from allowing the bracket body to slide relative to the chassis.

According to the electronic assembly and the chassis assembly disclose by the above embodiments, when the tray is mounted on the chassis, the restriction cover covers the handheld part and prevents the handheld part from pivotally rotating the two mount parts relative to the bracket body, thereby preventing the handle from allowing the bracket body to slide relative to the chassis. Therefore, as long as the tray configured to dispose the display card is mounted on the chassis, the bracket body configured to dispose the riser card cannot be removed from the chassis. In this way, it may prevent the riser card assembly from being removed from the chassis before the display card assembly is removed from the chassis, thereby preventing damage to the connectors on the display card assembly and the riser card assembly that butt against each other.

### BRIEF DESCRIPTION OF THE DRAWINGS

The present invention will become more fully understood from the detailed description given hereinbelow and the accompanying drawings which are given by way of illustration only and thus are not limitative of the present invention and wherein:

FIG. 1 is a perspective view of an electronic assembly according to one embodiment of the present invention;

FIG. 2 is an exploded perspective view of the electronic assembly shown in FIG. 1;

FIG. 3 is a partially enlarged perspective view of a riser card assembly and a display card assembly of the electronic assembly shown in FIG. 1;

FIG. 4 is a top view of the riser card assembly and the display card assembly shown in FIG. 3;

FIG. 5 is an exploded perspective view of the riser card assembly and the display card assembly shown in FIG. 3;

FIG. 6 is a side cross-sectional view of the electronic assembly shown in FIG. 1 that is partially enlarged;

FIG. 7 is a perspective view illustrating that the display card assembly of the electronic assembly shown in FIG. 1 is removed from the chassis; and

FIG. 8 is a side cross-sectional view of the electronic assembly shown in FIG. 7 that is partially enlarged.

### DETAILED DESCRIPTION

In the following detailed description, the features and advantages of embodiments of the present invention are described in sufficient detail to enable a person skilled in the art to understand and practice the embodiments of the present invention. A person skilled in the art may readily comprehend the objectives and advantages of the present invention based on the descriptions disclosed in this specification, the appended claims, and the accompanying drawings. The embodiments described below provide further detailed explanations of the principles of the present invention but are not intended to limit the scope of the present invention in any manner.

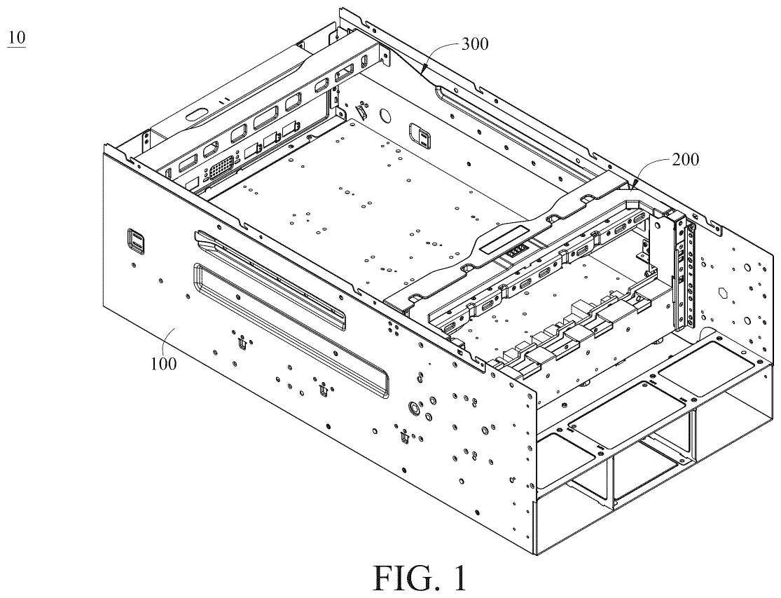

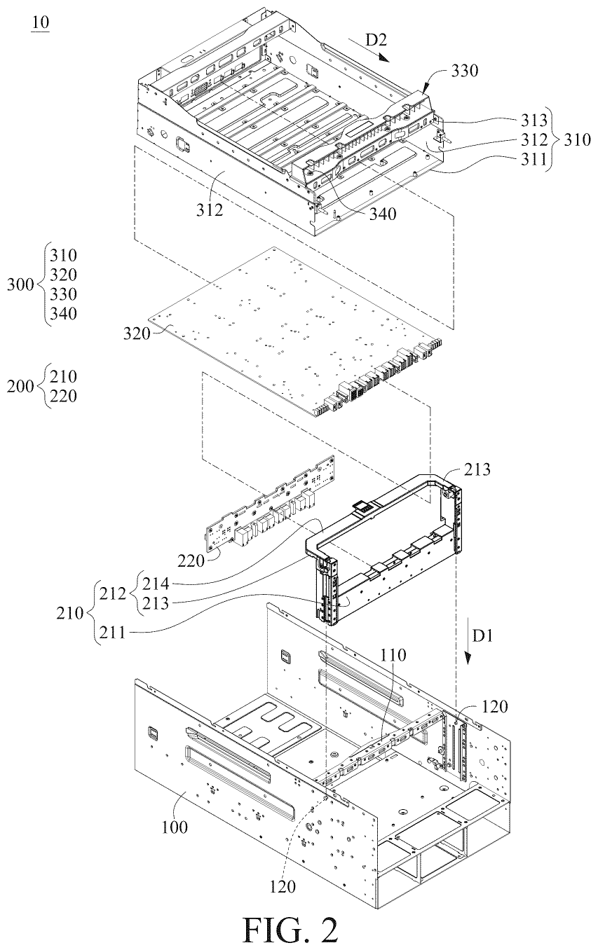

Please refer to FIG. 1 and FIG. 2. FIG. 1 is a perspective view of an electronic assembly according to one embodiment of the present invention. FIG. 2 is an exploded perspective view of the electronic assembly shown in FIG. 1.

In this embodiment, the electronic assembly 10 includes a chassis 100, a riser card assembly 200, and a display card assembly 300. The chassis 100 includes a fixing bracket 110 and two pins 120. The chassis 100 may, for example, be a server chassis or a server housing. In addition, the display card assembly 300 may, for example, be a Graphics Processing Unit (GPU) assembly; but the present invention is not limited thereto.

In this embodiment, the riser card assembly 200 includes an assembly bracket 210 and a riser card 220. The assembly bracket 210 includes a bracket body 211 and a handle 212. The handle 212 includes two mount parts 213 and a handheld part 214. The handheld part 214 connects the two mount parts 213. The two mount parts 213 are pivotally connected to opposite sides of the bracket body 211, respectively. The riser card 220 is disposed on the bracket body 211. The bracket body 211 is slidably disposed on the chassis 100 along a first mount direction D1.

In this embodiment, the display card assembly 300 includes, for example, a tray 310, a display card 320, a restriction cover 330, and a plurality of fasteners 340. The tray 310 is slidably disposed on the chassis 100 along a second mount direction D2. The first mount direction D1 is different from the second mount direction D2. That is, the bracket body 211 of the riser card assembly 200 and the tray 310 of the display card assembly 300 are disposed along different directions in the chassis 100. For example, in this embodiment, the first mounting direction D1 and the second mounting direction D2 are, for instance, perpendicular to each other.

In this embodiment, the tray 310 includes, for example, a bottom plate 311, two lateral plates 312 and a support bracket 313. The two lateral plates 312 are connected to opposite sides of the bottom plate 311, respectively. The support bracket 313 connects the two lateral plates 312 and is located on a side of the two lateral plates 312 located away from the bottom plate 311 The display card 320 is disposed on the bottom plate 311 and electrically connected to the riser card 220. The restriction cover is, for example, fixed to a side of the support bracket 313 located away from the bottom plate 311.

It should be noted that the chassis 100, the assembly bracket 210, the tray 310, and the restriction cover 330 may collectively be referred as a chassis assembly.

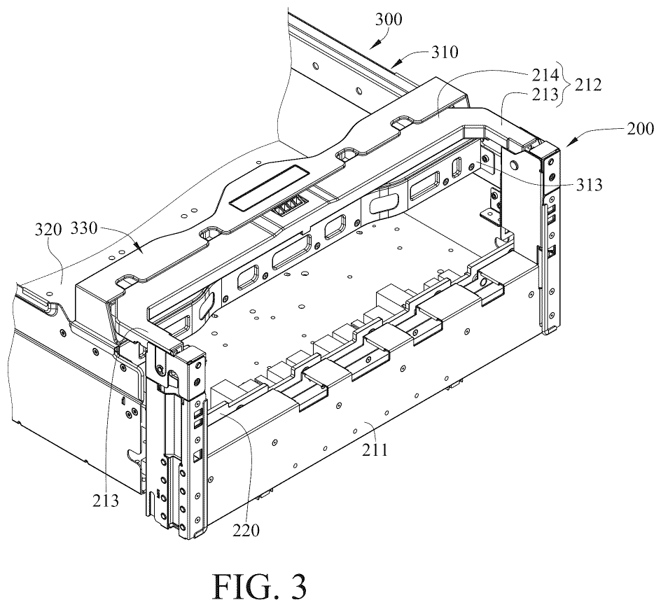

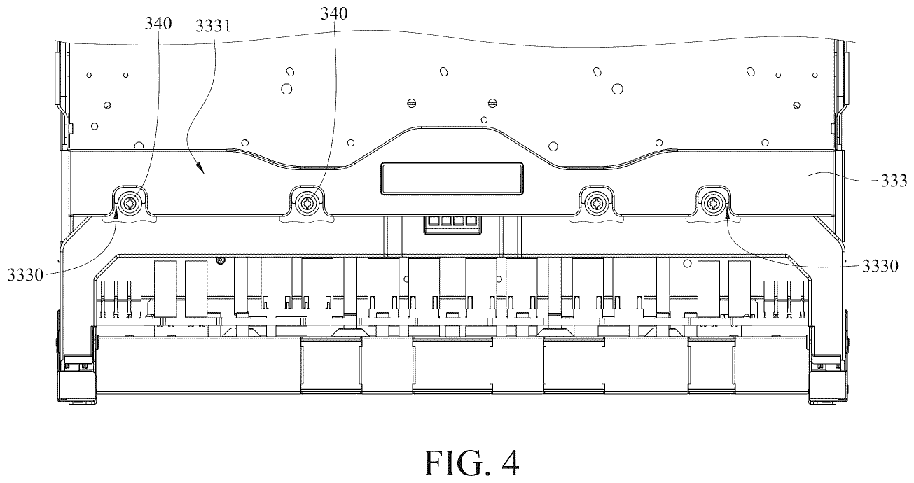

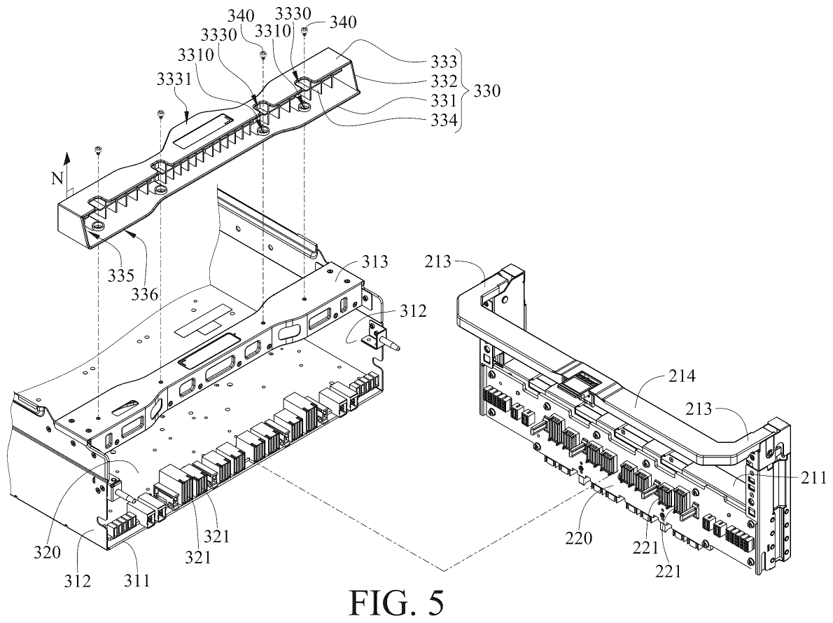

Referring to FIG. 3 to FIG. 5, FIG. 3 is a partially enlarged view of the perspective view of a riser card assembly and a display card assembly of the electronic assembly shown in FIG. 1. FIG. 4 is a top view of the riser card assembly and the display card assembly shown in FIG. 3. FIG. 5 is an exploded perspective view of the riser card assembly and the display card assembly shown in FIG. 3. In detail, in this embodiment, the restriction cover 330 is made of, for example, plastic and includes a mount plate 331, a connection plate 332, a restriction plate 333, and a plurality of ribs 334. The mount plate 331 and the restriction plate 333 are respectively connected to two opposite sides of the connection plate 332. The connection plate 332 is approximately in, for example, a U-shape. The mount plate 331, the connection plate 332, and the restriction plate 333 together form a restriction space 335 and an opening 336. The opening 336 is connected to the restriction space 335. The mount plate 331 is fixed to a side of the support bracket 313 located away from the bottom plate 311. For example, the mount plate 331 includes a plurality of fastening holes 3310. The fasteners 340 are respectively fastened into the fastening holes 3310 to fix the mount plate 331 and the support bracket 313. The ribs 334 are located in the restriction space 335 and connect the mount plate 331, the connection plate 332, and the restriction plate 333 to enhance the structural strength of the restriction cover 330. However, the present invention is not limited thereto. In other embodiments, the restriction cover may not include the ribs 334.

In addition, in this embodiment, as shown in FIG. 4 and FIG. 5, the restriction plate 333 includes, for example, a plurality of through holes 3330. The through holes 3330 respectively overlap with the corresponding fasteners 340 and fastening holes 3310. In other words, the through holes 3330 respectively overlap, along a normal direction N of a top surface 3331 of the restriction plate 333 that faces away from the mount plate 331, with the corresponding fasteners 340 and fastening holes 3310. It should be noted that, in FIG. 4, a part of the handheld part 214 is omitted to clearly illustrate the feature of the through holes 3330 overlapping with the fasteners 340 and fastening holes 3310. In other embodiments, there may be one fastener, one fastening hole, and one through hole. Alternatively, in still other embodiments, the fasteners, the fastening holes, and the through holes may be omitted and the restriction cover may be fixed to the support plate via welding or soldering.

As shown in FIG. 5, the display card 320 and the riser card 220 are electrically connected in a board-to-board manner via, for example, connectors 321 and 221.

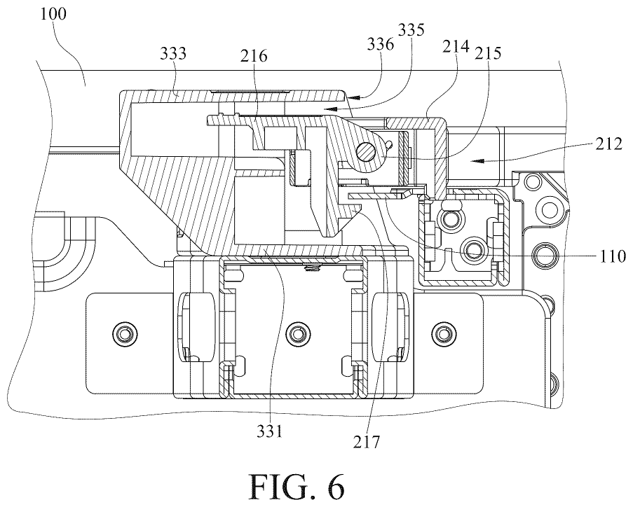

Furthermore, referring to FIG. 6, which is a partially enlarged view of a schematic side sectional view of the electronic assembly shown in FIG. 1. In this embodiment, the handle 212 further includes a positioning member 215. The positioning member 215 is disposed on the handheld part 214 and is detachably engaged with the fixing bracket 110 of the chassis 100 to hold the handheld part 214 in position or release the same relative to the chassis 100.

As shown in FIG. 1, FIG. 2, and FIG. 6, when the tray 310 is mounted on the chassis 100, the restriction cover 330 covers, for example, the positioning member 215 and a holding part 216 of the handheld part 214 to prevent the positioning member 215 from releasing the handheld part 214 relative to the chassis 100 (i.e., to prevent an engagement part 217 of the positioning member 215 from being disengaged from the fixing bracket 110). Specifically, the handheld part 214, for example, passes through the opening 336 and is at least partially located in the restriction space 335, and the restriction plate 333 is located on a side of the handheld part 214 located away from the mount plate 331. In this way, the handheld part 214 is prevented from forcing the two mount parts 213 to be pivoted relative to the bracket body 211, thereby preventing the handle 212 from forcing the bracket body 211 to slide relative to the chassis 100.

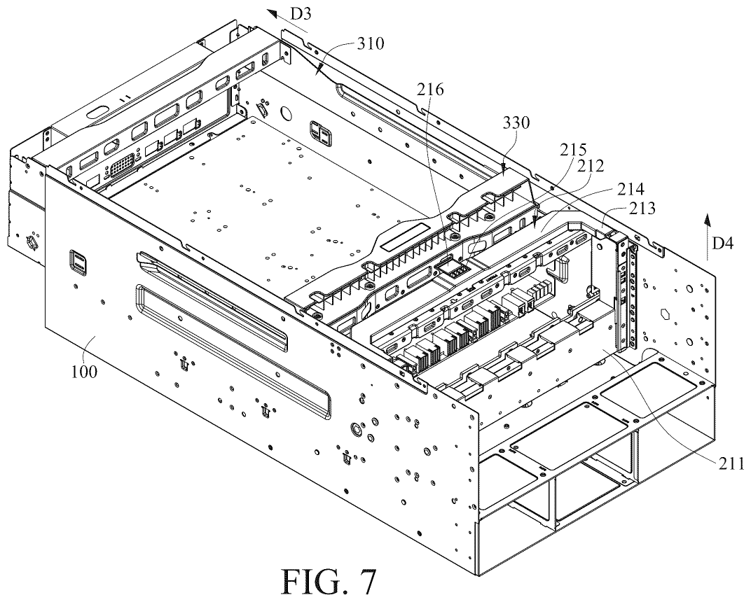

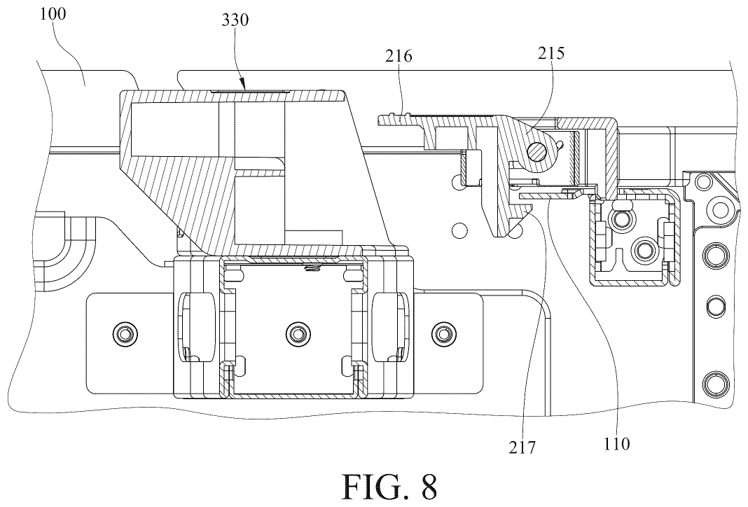

Referring to FIG. 2, FIG. 7, and FIG. 8, FIG. 7 is a perspective view illustrating the display card assembly being removed from the chassis in the electronic assembly shown in FIG. 1. FIG. 8 is a partially enlarged view of a schematic side sectional view of the electronic assembly shown in FIG. 7.

When the tray 310 is removed from the chassis 100 in a first disassembly direction D3 opposite to the second mount direction D2, the restriction cover 330 no longer covers the handheld part 214 and the holding part 216 of the positioning member 215, thereby exposing the handheld part 214 and the holding part 216 of the positioning member 215. Therefore, the holding part 216 of the positioning member 215 is allowed to be moved to release the handheld part 214 relative to the chassis 100 (i.e., to allow the engagement part 217 of the positioning member 215 to be disengaged from the fixing bracket 110). In this way, the handheld part 214 is allowed to force the two mount parts 213 to be pivoted relative to the bracket body 211, thereby, with the cooperation of the handle 212 and the two pins 120 of the chassis 100, allowing the bracket body 211 to be removed from the chassis 100 by sliding relative to the chassis 100 in a second disassembly direction D4 opposite to the first mount direction D1.

According to the electronic assembly and the chassis assembly disclosed in the above embodiment, when the tray is assembled on the chassis, the restriction cover covers the handheld part. Thus, the handheld part is prevented from forcing the two mount parts to be pivoted relative to the bracket body, thereby preventing the handle from forcing the bracket body to slide relative to the chassis. Therefore, as long as the tray for the display card to be disposed thereon is assembled on the chassis, the bracket body for the riser card to be disposed thereon is not allowed to be removed from the chassis. In this way, it may prevent the riser card assembly from being removed from the chassis before the display card assembly is removed from the chassis, thereby preventing the connectors of the display card assembly and the riser card assembly that are connected from being damaged.

The electronic assembly and the chassis assembly provided in this embodiment may be applied, for example, in a server host, and the server host may apply artificial intelligence (AI) computing, edge computing, or may be used as a 5G servers, a cloud servers, or a Vehicle-to-everything (V2X) server.

It will be apparent to those skilled in the art that various modifications and variations can be made to the present invention. It is intended that the specification and examples be considered as exemplary embodiments only, with a scope of the invention being indicated by the following claims and their equivalents.

What is claimed is:

1. An electronic assembly, comprising:
a chassis;
a riser card assembly, comprising an assembly bracket and a riser card, wherein the assembly bracket comprises a bracket body and a handle, the handle comprises two mount parts and a handheld part, the handheld part connects the two mount parts, the two mount parts are pivotally connected to two opposite sides of the bracket body, respectively, the riser card is disposed on the bracket body, and the bracket body is slidably disposed on the chassis along a first mount direction; and
a display card assembly, comprising a tray, a display card and a restriction cover, wherein the display card is disposed on the tray and electrically connected to the riser card, the restriction cover is disposed on a side of the tray, the tray is slidably disposed on the chassis along a second mount direction, and the first mount direction is different from the second mount direction;
wherein, when the tray is assembled on the chassis, the restriction cover covers the handheld part and prevents the handheld part from forcing the two mount parts to be pivoted relative to the assembly bracket, thereby preventing the handle from forcing the bracket body to slide relative to the chassis.

2. The electronic assembly according to claim 1, wherein the tray comprises a bottom plate, two lateral plates and a support bracket, the two lateral plates are connected to opposite sides of the bottom plate, respectively, the support bracket connects the two lateral plates and located on sides of the two lateral plates located away from the bottom plate, the display card is disposed on the bottom plate, and the restriction cover is fixed to a side of the support bracket located away from the bottom plate.

3. The electronic assembly according to claim 2, wherein the restriction cover comprises a mount plate, a connection plate and a restriction plate, the mount plate and the restriction plate are connected to two opposite sides of the connection plate, respectively, the mount plate, the connection plate and the restriction plate together form a restriction space and an opening, the opening is connected to the restriction space, the mount plate is fixed to the side of the support bracket located away from the bottom plate, and when the tray is assembled on the chassis, the handheld part passes through the opening and is at least partially located in the restriction space, and the restriction plate is located on a side of the handheld part located away from the mount plate

4. The electronic assembly of claim 3, wherein the display card assembly further comprises at least one fastener, the mount plate comprises at least one fastening hole, the at least one fastener is fastened into the at least one fastening hole to fix the mount plate and the support bracket.

5. The electronic assembly of claim 4, wherein the restriction plate comprises at least one through hole, the at least one through hole overlaps with the at least one fastening hole corresponding thereto.

6. The electronic assembly of claim 3, wherein the restriction cover further comprises a plurality of ribs, the plurality of ribs are located in the restriction space and connect the mount plate, the connection plate, and the restriction plate.

7. The electronic assembly of claim 1, wherein the first mount direction and the second mount direction are perpendicular to each other.

8. The electronic assembly of claim 1, wherein the handle further comprises a positioning member, the positioning member is disposed on the handheld part, the positioning member is detachably engaged with the chassis to hold the handheld part in position or release the handheld part relative to the chassis, when the tray is assembled on the chassis, the restriction cover covers a holding part of the positioning member so as to prevent the positioning member from releasing the handheld part relative to the chassis.

9. The electronic assembly of claim 1, wherein the display card and the riser card are electrically connected in a board-to-board manner.

10. A chassis assembly, configured to dispose a display card and a riser card, the chassis assembly comprising:
a chassis;
an assembly bracket, comprising a bracket body and a handle, wherein the handle comprises two mount parts and a handheld part, the handheld part connects the two mount parts, the two mount parts are pivotally connected to two opposite sides of the bracket body, respectively, the bracket body is slidably disposed on the chassis along a first mount direction and configured to dispose the riser card;
a tray, slidably disposed on the chassis along a second mount direction and configured to dispose the display card, and the first mount direction being different from the second mount direction; and
a restriction cover, disposed on a side of the tray;
wherein, when the tray is assembled on the chassis, the restriction cover covers the handheld part and prevents the handheld part from forcing the two mount parts to be pivoted relative to the assembly bracket, thereby preventing the handle from forcing the bracket body to slide relative to the chassis.
